(19) United States
(12) Patent Application Publication
(10) Pub. No.: US 2017/0250121 A1
(43) Pub. Date: Aug. 31, 2017

(54) SEMICONDUCTOR-ACCOMMODATING TRAY AND COVER THEREFOR

(71) Applicant: Kostat, Inc., Seoul (KR)

(72) Inventors: Ki Kyeong HO, Incheon (KR); Yong Hun LEE, Gimpo-si (KR)

(73) Assignee: Kostat, Inc., Seoul (KR)

(21) Appl. No.: 15/441,726

(22) Filed: Feb. 24, 2017

(30) Foreign Application Priority Data
Feb. 25, 2016 (KR) 10-2016-0022821

(51) Int. Cl. H01L 23/373

(52) U.S. Cl. CPC H01L 23/373

(57) ABSTRACT

Provided are a semiconductor-accommodating tray and a cover therefor. The semiconductor-accommodating tray includes a heat-resistant base plate, a plurality of pocket parts disposed on the heat-resistant base plate and configured to accommodate semiconductor devices, a guide part disposed at an edge of each pocket part, and a carbonaceous conductive material layer coated on surfaces of the heat-resistant base plate, the pocket parts, and the guide parts. When the semiconductor-accommodating tray and the cover therefor are used, production of particles significantly decreases, and low and uniform electric resistance and excellent antistatic effects are obtained.

### CROSS-REFERENCE TO RELATED APPLICATION

This application claims the benefit of Korean Patent Application No. 10-2016-0022821, filed on Feb. 25, 2016, in the Korean Intellectual Property Office, the disclosure of which is incorporated herein in its entirety by reference.

### BACKGROUND

1. Field

One or more embodiments relate to semiconductor-accommodating trays and covers therefor, and more particularly, to semiconductor-accommodating trays exhibiting significantly low production of particles and having low and uniform electric resistance, and thus having excellent antistatic effects, and covers therefor.

2. Description of the Related Art

To manufacture semiconductor products, a variety of manufacturers cooperate with one another, and a product manufactured by a manufacturer needs to be carried to other manufacturer. The carried product may be a processed or treated wafer, a semiconductor chip manufactured by dicing the processed or treated wafer, or a semiconductor package encapsulated with a molding resin.

A tray is used to accommodate and deliver these semiconductor devices, for example, semiconductor chips or semiconductor packages. In some cases, a tray is accommodated in test equipment or heat-treatment equipment to perform a test or a treatment on semiconductor chips or semiconductor packages. In a high-temperature test or treatment, the tray requires heat resistance and also requires a predetermined electrical conductivity to rapidly remove unnecessary static electricity.

To manufacture trays for high-temperature environments, a composite material prepared by adding a conductive material to a heat-resistant resin is currently used. However, currently available trays have relatively high electric resistances and non-uniform electric resistances according to positions, and particles produced therefor are attached to semiconductor packages or semiconductor chips, which may be a cause of defects in semiconductor devices.

### SUMMARY

One or more embodiments include semiconductor-accommodating trays exhibiting significantly low production of particles and having low and uniform electric resistance, and thus having excellent antistatic effects.

One or more embodiments include covers for the semiconductor-accommodating trays described above.

Additional aspects will be set forth in part in the description which follows and, in part, will be apparent from the description, or may be learned by practice of the presented embodiments.

According to one or more embodiments, a semiconductor-accommodating tray includes a heat-resistant base plate, a plurality of pocket parts disposed on the heat-resistant base plate and configured to accommodate semiconductor devices, a guide part disposed at an edge of each pocket part, and a carbonaceous conductive material layer coated on surfaces of the heat-resistant base plate, the pocket parts, and the guide parts.

The carbonaceous conductive material layer may be a conductive polymer layer, and the conductive polymer layer may include at least one conductive polymer selected from the group consisting of polyaniline (PANI), polypyrrole (PPY), polycarbazole, polyindole, polyazepine, polynaphthalene, polythiophene (PT), poly(3,4-ethylenedioxythiophene) (PEDOT), poly(p-phenylene sulfide) (PPS), poly(p-phenylene vinylene) (PPV), polyacetylene (PAC), polypyrene, polyphenylene, polyfluorene, polyazulene, polyfuran, polythiophene vinylene, polypyridine, and derivatives thereof.

In some embodiments, the carbonaceous conductive material layer may include carbon nanotubes.

In addition, the carbonaceous conductive material layer may have a thickness of about 3 μm to about 20 μm.

The heat-resistant base plate may include a heat-resistant polymer capable of enduring a temperature of at least 130° C. In particular, the heat-resistant polymer may include at least one selected from modified polyphenylene oxide (MPPO), modified polysulfone (MPSU), polycarbonate (PC), polyamide, polysulfone (PSU), polyethersulfone (PES), polyetherimide (PEI), polyphenylene sulfide, liquid crystal polymer, and polyetheretherketone (PEEK). In addition, the heat-resistant polymer may not include an electrically conductive material.

An electric resistance between two points apart from each other by a distance of 1 cm, positioned at a surface of the semiconductor-accommodating tray, may be about 2.5×10⁶Ω or less.

According to one or more embodiments, a cover for a semiconductor-accommodating tray includes a heat-resistant base plate and a carbonaceous conductive material layer coated on a surface of the heat-resistant base plate.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view illustrating a semiconductor-accommodating tray according to an embodiment and a cover therefor;

FIG. 2 is an enlarged view of a region II of FIG. 1;

FIG. 3 is a cross-sectional view taken along line III-III′ of FIG. 2;

FIG. 4 is a side cross-sectional view illustrating a partial cross-section of the cover illustrated in FIG. 1, i.e., a cross-section of a portion of the cover, corresponding to the line III-III′ of FIG. 2;

FIG. 5 is an image showing a sample subjected to a resistance uniformity test, according to embodiments and measurement positions thereof;

FIG. 6 is an image showing sloughing test results of samples of Example 1 and Comparative Example 1; and

FIG. 7 illustrates images showing taping test results of the samples of Example 1 and Comparative Example 1.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items.

Hereinafter, exemplary embodiments of the present disclosure will be described with reference to the accompanying drawings. However, the present disclosure may be embodied in many different forms and should not be construed as being limited to embodiments set forth herein. Rather, these embodiments are provided so that this disclosure will be thorough and complete, and will fully convey the scope of the present disclosure to those skilled in the art. The same reference numerals refer to the same constitutional elements throughout the drawings. Further, a variety of elements and regions in the drawings are schematically illustrated. Thus, the present disclosure is not limited to the relative sizes or intervals shown in the accompanying drawings.

While such terms as “first,” “second,” etc., may be used to describe various components, such components must not be limited to the above terms. The above terms are used only to distinguish one component from another. For example, a first element may be named a second element without departing from the scope of the inventive concept, and the second element may also be named the first element.

The terms used in the present specification are merely used to describe particular embodiments, and are not intended to limit the inventive concept. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

All terms used herein including technical or scientific terms have the same meaning as those generally understood by those of ordinary skill in the art unless they are defined differently. It should be understood that terms generally used, which are defined in a dictionary, have the same meaning as in a context of related technology, and the terms are not understood as excessively formal meaning unless they are clearly defined in the application.

When an embodiment may be implemented in a different way, particular processes may be performed in a different order from that has been described herein. For example, two consecutively described processes may be performed substantially at the same time, or may be performed in an order opposite to the described order.

In the accompanying drawings, variations from the shapes of the illustrations, for example, of manufacturing techniques and/or tolerances, are to be expected. Thus, embodiments of the present disclosure should not be construed as limited to the particular shapes of regions illustrated herein but are to include deviations in shapes that result, for example, from manufacturing. As used herein, the term “and/or” includes any and all combinations of one or more of the associated listed items. In addition, the term “substrate” as used herein refers to a substrate itself, or a stacked structure including a substrate and a predetermined layer, film or the like formed on a surface thereof. In addition, the term “a surface of a substrate” as used herein may mean an exposed surface of the substrate itself, or an outer surface of a predetermined layer, film or the like formed on the substrate.

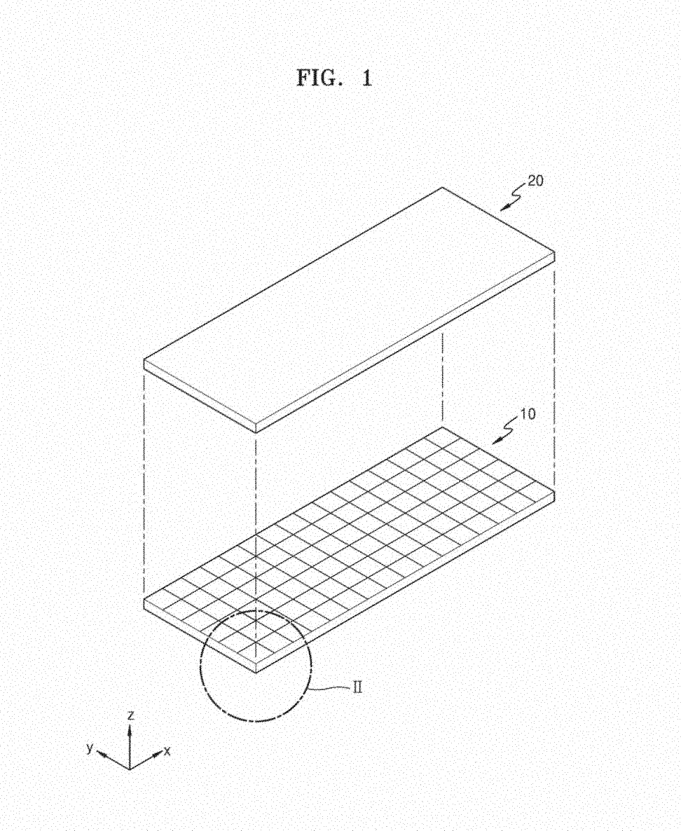

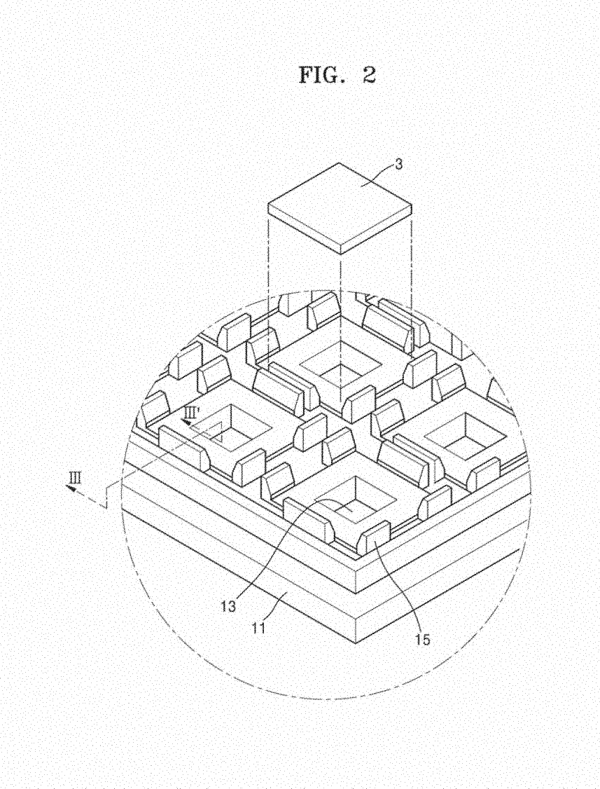

FIG. 1 is a perspective view illustrating a semiconductor-accommodating tray 10 according to an embodiment and a cover 20 therefor. FIG. 2 is an enlarged view of a region II of FIG. 1.

Referring to FIGS. 1 and 2, the semiconductor-accommodating tray 10 may include a plurality of pocket parts 13 on a base plate 11 to accommodate semiconductor devices such as semiconductor chips or semiconductor packages. The pocket parts 13 may be arranged on the base plate 11 in a lattice form. Although FIG. 1 illustrates that sixteen (16) pocket parts 13 are arranged in an x direction and six (6) pocket parts 13 are arranged in a y direction, the present disclosure is not limited to the above example.

The base plate 11 may be formed of a heat-resistant polymer material. As used herein, the term “heat-resistant” is defined as a property capable of enduring a high temperature of about 130° C. or higher.

The heat-resistant polymer material of the base plate 11 may be, for example, at least one selected from the group consisting of modified polyphenylene oxide (MPPO), modified polysulfone (MPSU), polycarbonate (PC), polyamide, polysulfone (PSU), polyethersulfone (PES), polyetherimide (PEI), polyphenylene sulfide, liquid crystal polymer, and polyetheretherketone (PEEK), but the present disclosure is not limited to the above examples. In some embodiments, the heat-resistant polymer may include no electrically conductive material.

The pocket parts 13 may have a shape of semiconductor devices to be accommodated. Although FIG. 1 illustrates that the pocket parts 13 have a tetragonal shape, the present disclosure is not limited to the above example. The pocket parts 13 may have various shapes, such as a hexagonal, circular or oval shape, or the like.

Each pocket part 13 may be provided with guide parts 15 protruding in a vertical direction at edges thereof. When a semiconductor device 3 is accommodated on the pocket part 13, the guide parts 15 may guide the semiconductor device 3. In particular, side surfaces of the guide parts 15, facing the pocket part 13, may be inclined. Since the side surfaces of the guide parts 15, facing the pocket part 13, are inclined, the semiconductor device 3 may be smoothly guided in the pocket part 13 although the semiconductor device 3 accommodated in the pocket part 13 is not accurately aligned. The inclination of the side surfaces of the guide parts 15 may be appropriately selected in consideration of the size, alignment accuracy, and the like of the semiconductor device 3 to be accommodated.

The guide parts 15 may be disposed on all four sides of the pocket part 13 or only on two opposite sides thereof. In another embodiment, the guide parts 15 may be configured such that one guide part 15 or at least two guide parts 15 may be disposed on one side of the pocket part 13. Although FIG. 2 illustrates that one guide part 15 is disposed on a side in a y direction and two guide parts 15 are disposed on a side in an x direction, the present disclosure is not limited to the above example.

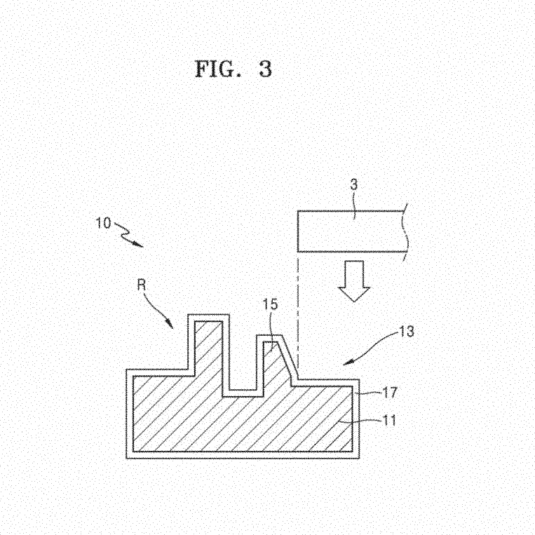

FIG. 3 is a cross-sectional view taken along line III-III′ of FIG. 2.

Referring to FIG. 3, a carbonaceous conductive material layer 17 may be disposed on surfaces of the base plate 11, the pocket part 13, and the guide part 15. The carbonaceous conductive material layer 17 may have a thickness of, for example, about 3 μm to about 20 μm. When the thickness of the carbonaceous conductive material layer is too small, electric resistance excessively increases and thus static electricity may be unsatisfactorily removed from the semiconductor-accommodating tray. On the other hand, when the thickness of the carbonaceous conductive material layer 17 is too large, manufacturing costs may increase.

The carbonaceous conductive material layer 17 may be a conductive polymer layer. A conductive polymer constituting the conductive polymer layer may be, for example, at least one selected from the group consisting of polyaniline (PANI), polypyrrole (PPY), polycarbazole, polyindole, polyazepine, polynaphthalene, polythiophene (PT), poly(3,4-ethylenedioxythiophene) (PEDOT), poly(p-phenylene sulfide) (PPS), poly(p-phenylene vinylene) (PPV), polyacetylene (PAC), polypyrene, polyphenylene, polyfluorene, polyazulene, polyfuran, polythiophene vinylene, polypyridine, and derivatives thereof, but the present disclosure is not limited to the above examples. The conductive polymer layer may be formed of any polymer with electrical conductivity.

In some embodiments, the carbonaceous conductive material layer 17 may include a carbonaceous nanomaterial such as carbon nanotubes, carbon nanowires, carbon nanorods, graphene, or pullerene. For example, carbon nanotubes (CNTs) included in the carbonaceous conductive material layer 17 may be single wall CNTs or multiple wall CNTs.

The carbonaceous conductive material layer 17 may be formed of a carbonaceous nanomaterial alone, such as carbon nanotubes, carbon nanowires, carbon nanorods, graphene, or pullerene. In another embodiment, the carbonaceous conductive material layer 17 may be a layer formed by combining such carbonaceous nanomaterials using a binder such as a polymer material. The binder may be, for example, a hydrophobic polymer such as polytetrafluoroethylene (PTFE), but the present disclosure is not limited thereto.

The carbonaceous conductive material layer 17 may have an electric resistance of less than 2.5×10⁶Ω when measured at two points apart from each other by a distance of within 1 cm. When the electric resistance of the carbonaceous conductive material layer 17 is too high, static electricity may be unsatisfactorily removed from the semiconductor-accommodating tray 10. In this case, semiconductor devices accommodated may be damaged.

The carbonaceous conductive material layer 17 may be formed using one of various methods, for example, spin coating, dipping, spraying, doctor blade, and the like, but the present disclosure is not limited to the above examples. In addition, when the carbonaceous conductive material layer 17 is formed of a conductive polymer, the carbonaceous conductive material layer 17 may be obtained by forming a fluidized layer of the conductive polymer and drying the fluidized layer at a temperature ranging from about 90° C. to about 150° C. for about 10 minutes to about 1 hour.

As described above, electrical conductivity according to positions may be more uniform by forming the carbonaceous conductive material layer 17 on the heat-resistant base 11 by coating.

In addition, as compared to the related art in which electrically conductive components are added, production of particles may be significantly decreased.

In addition, since a heat-resistant polymer is used as a material of the heat-resistant base plate 11 instead of a general polymer, the semiconductor-accommodating tray 10 may be used to carry semiconductor devices and accommodate semiconductor devices for a test at a high temperature.

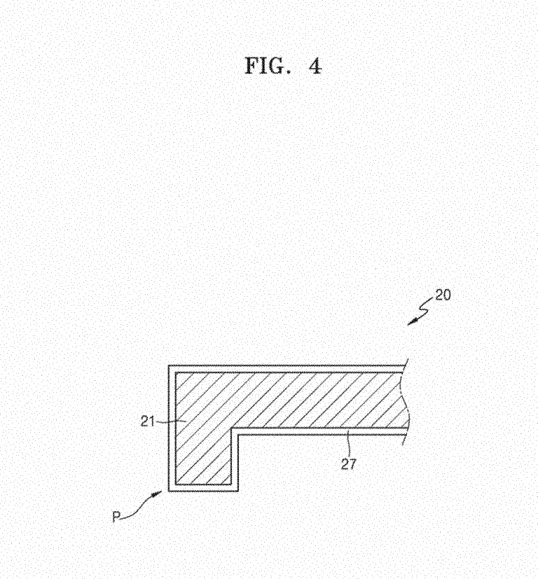

FIG. 4 is a side cross-sectional view illustrating a partial cross-section of the cover illustrated in FIG. 1, i.e., a cross-section of a portion of the cover 20, corresponding to the line III-III′ of FIG. 2.

Referring to FIG. 4, the cover 20 may be provided with a protrusion P at an edge thereof to be coupled to a recess R (see FIG. 3) at an edge of the semiconductor-accommodating tray 10 to correspond to the protrusion P. When the semiconductor-accommodating tray 10 and the cover 20 are coupled together, the protrusion P is engaged with the recess R and alignment of the semiconductor-accommodating tray 10 and the cover 20 may be maintained even if a lateral external force is applied. Although the semiconductor-accommodating tray 10 is illustrated as having a smooth lower surface, it will be obvious to one of ordinary skill in the art that the semiconductor-accommodating tray 10 is provided with the protrusion as described above at a lower portion thereof and thus a plurality of the semiconductor-accommodating tray 10 may be conveniently stacked as multiple layers and maintain the stack against a lateral external force.

In addition, the cover 20 may include a base plate 21 and a carbonaceous conductive material layer 27.

The base plate 21 is identical to the base plate 11 described above with reference to FIGS. 1 and 2, and thus a detailed description thereof will not be provided herein.

In addition, the carbonaceous conductive material layer 27 may be at least partially coated on a surface of the base plate 21. Material, thickness, formation method, and the like of the carbonaceous conductive material layer 27 have already been described with reference to FIG. 3, and thus a detailed description thereof will not be provided herein. In some embodiments, the carbonaceous conductive material layer 27 may be coated on the entire surface of the base plate 21.

When the semiconductor-accommodating tray 10 and the cover 20 therefor as described above are used, the production of particles significantly decreases and low and uniform electric resistance and excellent antistatic effects may be obtained.

Hereinafter, configurations and effects of the present disclosure will be described in further detail with reference to the following example and comparative example. These examples are provided for illustrative purposes only and are not intended to limit the scope of the present disclosure.

Resistance Uniformity Test

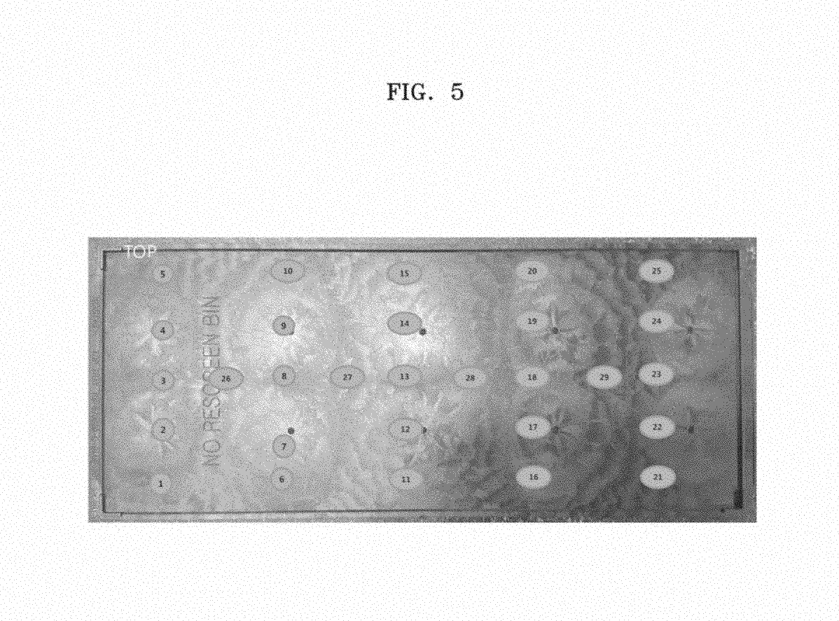

FIG. 5 is an image showing samples having undergone a resistance uniformity test, according to embodiments and measurement positions thereof.

First, a sample according to an embodiment, prepared by coating poly(3,4-ethylenedioxythiophene (PEDOT) on a modified polyphenylene oxide (MPPO) base plate, was prepared (Example 1). As a sample according to the related art, an MPPO composite material in which a carbon fiber and carbon powder were added prepared (Comparative Example 1).

As illustrated in FIG. 5, resistances of the two samples were measured at 29 positions, and the resistances were measured at the corresponding positions in a state in which two electrodes of a tester were spaced apart from each other by a distance of about 1 cm. The measurement results thereof are shown in Table 1 below.

TABLE 1

| Measurement | Example 1 | Comparative Example 1 |
|---|---|---|
| position | (Ω) | (Ω) |
| 1 | 4.92E+05 | 1.72E+05 |
| 2 | 3.19E+0.5 | 4.44E+08 |
| 3 | 4.38E+05 | 1.03E+03 |
| 4 | 1.97E+05 | 1.69E+08 |
| 5 | 1.16E+06 | 4.42E+03 |
| 6 | 2.36E+06 | 3.49E+06 |
| 7 | 2.25E+05 | 6.67E+08 |
| 8 | 3.46E+05 | 1.08E+03 |
| 9 | 3.20E+05 | 8.93E+07 |
| 10 | 2.01E+05 | 4.62E+05 |
| 11 | 2.48E+05 | 1.59E+04 |
| 12 | 1.24E+06 | 7.97E+10 |
| 13 | 4.92E+05 | 2.36E+03 |
| 14 | 5.16E+05 | 1.52E+09 |
| 15 | 6.09E+05 | 3.36E+04 |
| 16 | 3.18E+05 | 1.06E+04 |
| 17 | 2.09E+05 | 1.37E+07 |
| 18 | 2.71E+05 | 3.19E+03 |
| 19 | 3.01E+05 | 7.96E+07 |
| 20 | 1.35E+06 | 1.18E+04 |
| 21 | 1.34E+06 | 1.04E+06 |
| 22 | 1.48E+05 | 4.90E+08 |
| 23 | 1.76E+06 | 1.00E+03 |
| 24 | 1.47E+05 | 2.27E+09 |
| 25 | 1.57E+05 | 3.30E+04 |
| 26 | 3.68E+05 | 2.34E+05 |
| 27 | 1.17E+06 | 2.72E+03 |
| 28 | 3.33E+05 | 4.03E+05 |
| 29 | 1.24E+06 | 1.02E+04 |
| Average | 6.30E+05 | 2.95E+09 |
| Standard | 5.67E+05 | 1.48E+10 |
| deviation | | |

As shown in Table 1 above, it is confirmed that the average resistance of the sample of Example 1 was much lower than that of the sample of Comparative Example 1. In addition, the sample of Example 1 exhibited a very low degree of dispersion of resistances according to positions, represented as a standard deviation. Thus, it is confirmed that the semiconductor-accommodating tray and/or the cover therefor according to the embodiment had a very uniform resistance according to positions and a low average resistance. Therefore, the semiconductor-accommodating tray and/or the cover therefor according to the embodiment may have enhanced antistatic effects.

Particle Production Characteristic Test

To confirm how much particles as a contaminant were produced, an abrasion resistance test, a sloughing test, and a taping test were performed on the samples of Example 1 and Comparative Example 1.

1) Abrasion Resistance Test

Abrasion resistance was evaluated using a taber abrasion tester. CS-17 was used as a material for testing the abrasion resistance and a rotating speed thereof was 60 rpm. A degree of abrasion was determined by a decrease in mass after 1000 rotations.

As a result, the sample of Example 1 exhibited a mass change of 63.5 mg, while the sample of Comparative Example 1 exhibited a mass change of 68.1 mg. That is, it is confirmed that the sample of Example 1 had higher abrasion resistance than the sample of Comparative Example 1.

2) Sloughing Test

Each of the samples of Example 1 and Comparative Example 1 was rubbed with a constant force against printing paper to evaluate how much particles thereof were smeared on the printing paper (sloughing test).

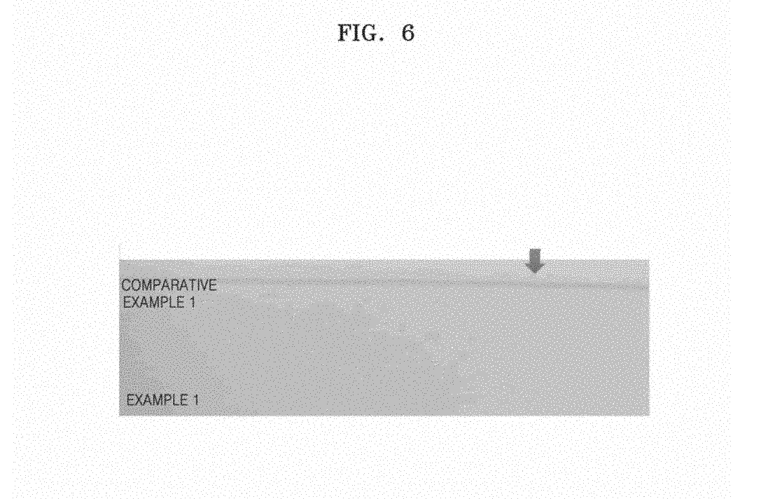

FIG. 6 is an image showing sloughing test results of the samples of Example 1 and Comparative Example 1.

Referring to FIG. 6, it was clearly observed with even the naked eye that the particles of the sample of Comparative Example 1 were smeared on the printing paper (see a portion represented by the arrow).

In contrast, the particles of the sample of Example 1 were less smeared, which was difficult to see with the naked eye.

3) Taping Test

A transparent tape was attached to each of the samples of Example 1 and Comparative Example 1 and then detached in a direction of 90 degrees with respect to a surface of each sample. To more easily observe particles of each sample smeared on the transparent tape, each transparent tape was attached to white paper, followed by capturing an image thereof.

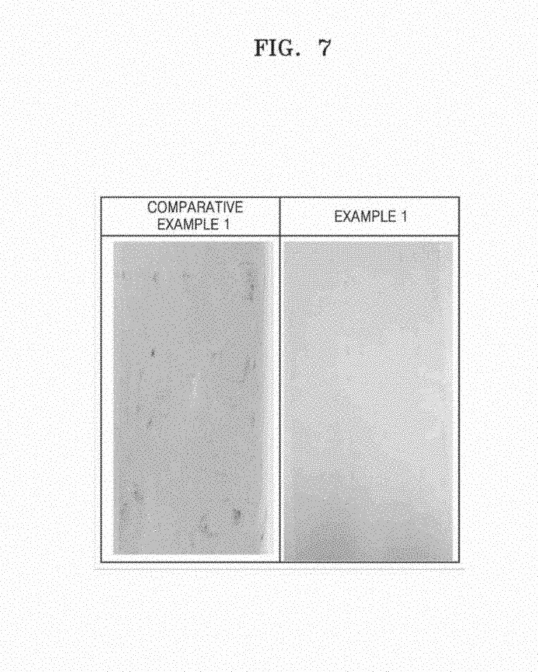

FIG. 7 illustrates images showing taping test results of the samples of Example 1 and Comparative Example 1.

As illustrated in FIG. 7, it is confirmed that the sample of Example 1 exhibited far much lower production of particles than the sample of Comparative Example 1.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the inventive concept as defined by the following claims.

What is claimed is:

1. A semiconductor-accommodating tray comprising:
a heat-resistant base plate;
a plurality of pocket parts disposed on the heat-resistant base plate and configured to accommodate semiconductor devices;
a guide part disposed at an edge of each pocket part; and
a carbonaceous conductive material layer coated on surfaces of the heat-resistant base plate, the pocket parts, and the guide parts.

2. The semiconductor-accommodating tray of claim 1, wherein the carbonaceous conductive material layer comprises a conductive polymer layer, wherein the conductive polymer layer comprises at least one conductive polymer selected from the group consisting of polyaniline (PANI), polypyrrole (PPY), polycarbazole, polyindole, polyazepine, polynaphthalene, polythiophene (PT), poly(3,4-ethylenedioxythiophene) (PEDOT), poly(p-phenylene sulfide) (PPS), poly(p-phenylene vinylene) (PPV), polyacetylene (PAC), polypyrene, polyphenylene, polyfluorene, polyazulene, polyfuran, polythiophene vinylene, polypyridine, and derivatives thereof.

3. The semiconductor-accommodating tray of claim 1, wherein the carbonaceous conductive material layer comprises carbon nanotubes.

4. The semiconductor-accommodating tray of claim 1, wherein the carbonaceous conductive material layer has a thickness of about 3 μm to about 20 μm.

5. The semiconductor-accommodating tray of claim 1, wherein the heat-resistant base plate comprises a heat-resistant polymer capable of enduring a temperature of at least 130° C.

6. The semiconductor-accommodating tray of claim 5, wherein the heat-resistant polymer comprises at least one selected from modified polyphenylene oxide (MPPO), modified polysulfone (MPSU), polycarbonate (PC), polyamide, polysulfone (PSU), polyethersulfone (PES), polyetherimide (PEI), polyphenylene sulfide, liquid crystal polymer, and polyetheretherketone (PEEK).

7. The semiconductor-accommodating tray of claim 5, wherein the heat-resistant polymer comprises no electrically conductive material.

8. The semiconductor-accommodating tray of claim 1, wherein an electric resistance between two points apart from each other by a distance of 1 cm, positioned at a surface of the semiconductor-accommodating tray, is about 2.5×10⁶Ω or less.

9. A cover for a semiconductor-accommodating tray, the cover comprising:
a heat-resistant base plate; and
a carbonaceous conductive material layer coated on a surface of the heat-resistant base plate.
